(19) United States
(12) Patent Application Publication
(10) Pub. No.: US 2016/0225702 A1
(43) Pub. Date: Aug. 4, 2016

(54) SEMICONDUCTOR DEVICE AND MANUFACTURING METHOD THEREOF

(71) Applicant: Kabushiki Kaisha Toshiba, Tokyo (JP)

(72) Inventors: Hiroshi Kadono, Ibo Hyogo (JP); Masataka Namba, Himeji Hyogo (JP); Shinichi Kouyama, Himeji Hyogo (JP); Mineo Koga, Ibo Hyogo (JP)

(21) Appl. No.: 14/802,427

(22) Filed: Jul. 17, 2015

(30) Foreign Application Priority Data
Feb. 4, 2015 (JP) 2015-020167
Apr. 3, 2015 (JP) 2015-077107

(51) Int. Cl. H01L 23/495; H01L 21/56; H01L 23/00; H01L 23/31

(52) U.S. Cl. CPC H01L 23/49541; H01L 23/3114; H01L 21/56; H01L 24/92; H01L 24/83; H01L 24/85; H01L 24/32; H01L 24/48; H01L 24/73; H01L 2224/92247; H01L 2224/83801; H01L 2224/73265; H01L 2224/32245; H01L 2224/48245

(57) ABSTRACT

A semiconductor device according to an embodiment includes a metal part including a first surface and a second surface on an opposite side to the first surface. A semiconductor chip is mounted on the first surface of the metal part and is electrically connected to the metal part. A terminal part includes a third surface being in contact with the second surface of the metal part, a fourth surface on an opposite side to the third surface, and side surfaces between the third surface and the fourth surface. A resin is provided on the second surface of the metal part and the side surfaces of the terminal part.

### CROSS REFERENCE TO RELATED APPLICATIONS

This application is based upon and claims the benefit of priority from the prior Japanese Patent Applications No. 2015-077107, filed on Apr. 3, 2015 and No. 2015-020167, filed on Feb. 4, 2015, the entire contents of which are incorporated herein by reference.

### FIELD

The embodiments of the present invention relate to a semiconductor device and manufacturing method thereof.

### BACKGROUND

A semiconductor package such as LGA (Land Grid Array) has an electrode on the front or back surface thereof in some cases. To provide an electrode terminal on the front or back surface of the semiconductor package, an electrode portion of a lead frame is conventionally formed to protrude to expose the electrode portion from a sealing resin. To expose the electrode portion from the sealing resin in this manner, the lead frame of the semiconductor package is half-etched in advance to cause the electrode portion to protrude, without being formed to be flat.

The half-etched structure of the lead frame differs according to specifications of a package of a semiconductor device. Therefore, the structure of the lead frame needs to be different according to a type of a semiconductor package and cannot be commonalized. For example, when plural types of semiconductor packages being different in shapes, sizes, or positions of electrode terminals are to be manufactured, lead frames different according to the types of the semiconductor packages need to be used. In this case, each time a different type of a semiconductor device is to be packaged, the lead frame needs to be replaced and a time required for a packaging process of the semiconductor device becomes long.

The lead frame having the half-etched structure requires etching processing using a mask as well as pressing processing and thus it is more expensive than a flat lead frame (a lead frame having a flat frame structure). Therefore, preparation of the lead frame having the half-etched structure with respect to each of the types of the semiconductor packages leads to an increase in the cost of the semiconductor device. Furthermore, when the shape of the lead frame differs, processing conditions in a mounting process and a wire bonding process for a semiconductor chip need to be changed.

### BRIEF DESCRIPTION OF THE DRAWINGS

FIG. 1A shows an example of a configuration of a lead frame 1 to be used for semiconductor devices according to one embodiment;

FIG. 1B shows an example of a lead pattern 2 included in a frame C of the lead frame 1;

FIG. 2A is a plan view of the lead frame 1 within the dashed line frame 3;

FIG. 2B is a side view of the lead frame 1 within the dashed line frame 3;

FIGS. 3A to 3E showing an example of a configuration of an individualized semiconductor package 100;

FIGS. 4A to 4C are cross-sectional views showing an example of the manufacturing method of the semiconductor package 100 according to the present embodiment; and

FIG. 5 shows a portion of a mold 200.

### DETAILED DESCRIPTION

Embodiments will now be explained with reference to the accompanying drawings. The present invention is not limited to the embodiments.

A semiconductor device according to an embodiment includes a metal part including a first surface and a second surface on an opposite side to the first surface. A semiconductor chip is mounted on the first surface of the metal part and is electrically connected to the metal part. A terminal part includes a third surface being in contact with the second surface of the metal part, a fourth surface on an opposite side to the third surface, and side surfaces between the third surface and the fourth surface. A resin is provided on the second surface of the metal part and the side surfaces of the terminal part.

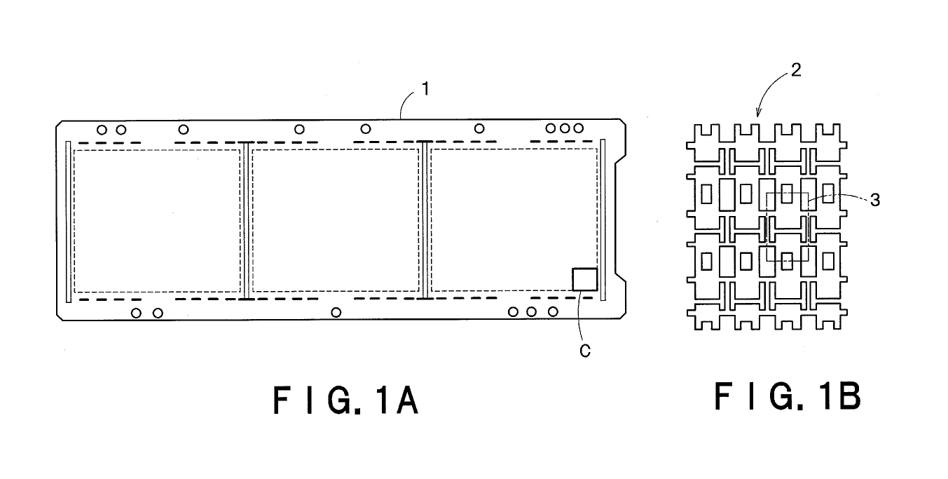

FIG. 1A shows an example of a configuration of a lead frame 1 to be used for semiconductor devices according to one embodiment. FIG. 1B shows an example of a lead pattern 2 included in a frame C of the lead frame 1. The lead frame 1 has repetitions of the lead pattern 2 shown in FIG. 1B. The lead pattern 2 shown in FIG. 1B has a region indicated by a dashed line frame 3 as one unit and a portion of the lead frame 1 in the dashed line frame 3 is used for packaging one semiconductor device.

As the lead frame 1, low-resistance and high-thermal-conductivity metal such as copper, nickel-plated copper, silver-plated copper, gold-plated copper, a copper alloy, or aluminum is used. The lead frame 1 is formed by pressing processing of such a metal plate.

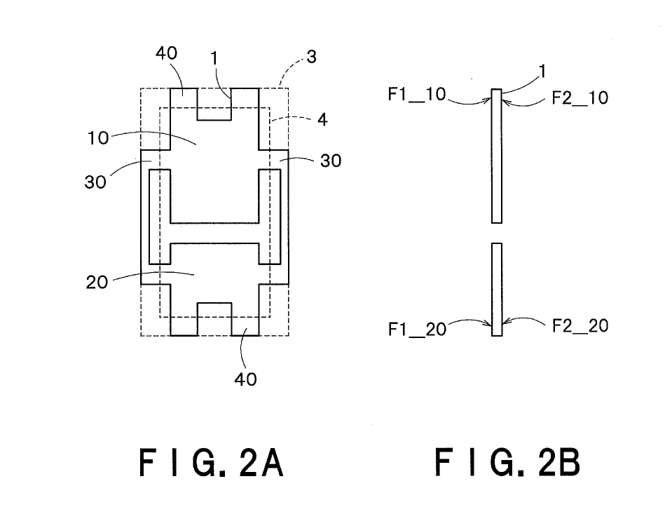

FIG. 2A is a plan view of the lead frame 1 within the dashed line frame 3. FIG. 2B is a side view of the lead frame 1 within the dashed line frame 3. The lead frame 1 includes a chip mount part (a bed part) 10, an electrode connection part (a post part) 20, first suspension leads 30, and second suspension leads 40.

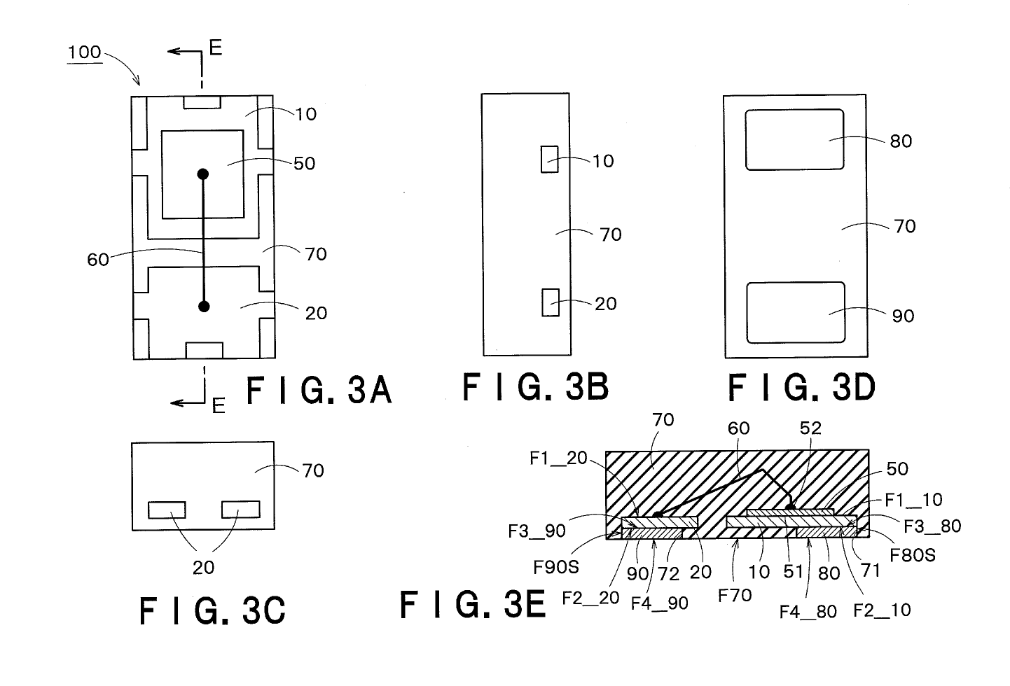

The chip mount part 10 is used as a bed part having a front surface on which a semiconductor chip 50 (see FIG. 3E) is mounted. The electrode connection part 20 is separated from the chip mount part 10 and is used as a post part electrically connected to an upper electrode (a source electrode, for example) of the semiconductor chip 50. The chip mount part 10 and the electrode connection part 20 being metal parts are flat as shown in FIG. 2B. The chip mount part 10 has a first surface F1_10 and a second surface F2_10 on the opposite side to the first surface F1_10. The electrode connection part 20 has a first surface F1_20 and a second surface F2_20 on the opposite side to the first surface F1_20. The first surfaces F1_10 and F1_20 and the second surfaces F2_10 and F2_20 are all flat and regions for forming electrode parts 80 and 90 (see FIG. 3D) are also substantially planar.

The first suspension leads 30 and the second suspension leads 40 are connected to the chip mount parts 10 and the electrode connection pats 20 of other units (other semiconductor packages) adjacent to the dashed line frame 3. Accordingly, a plurality of semiconductor packages are connected to the same lead frame 1 with the first suspension leads 30 and the second suspension leads 40 until they are cut off from the lead frame 1.

A dashed line frame 4 in FIG. 2A indicates a region in which the lead frame 1 is sealed with a resin. The first suspension leads 30 and the second suspension leads 40 outside the dashed line frame 4 are removed with a dicing blade when the semiconductor packages are to be cut off from the lead frame 1. In this way, the semiconductor packages are cut off from each other and individualized.

FIG. 3A is a plan view showing an example of a configuration of an individualized semiconductor package 100. In FIG. 3A, a configuration inside a resin 70 is shown for convenience sake. FIG. 3B is a side view of the semiconductor package 100, FIG. 3C is a front view of the semiconductor package 100, and FIG. 3D is a bottom view of the semiconductor package 100. FIG. 3E is a cross-sectional view along a line E-E in FIG. 3A.

The semiconductor package 100 as a semiconductor device includes the chip mount part (the bed part) 10, the electrode connection part (the post part) 20, a semiconductor chip 50, a metal wire 60, the resin 70, a first terminal part 80, and a second terminal part 90.

The semiconductor chip 50 includes an arbitrary semiconductor element on a semiconductor substrate. For example, the semiconductor chip 50 has electrodes of the semiconductor element on the front and back surfaces, respectively. As shown in FIG. 3E, the semiconductor chip 50 is placed on the chip mount part 10 and is fixed with a solder (not shown). The semiconductor chip 50 is mounted on the first surface F1_10 of the chip mount part 10 being a first metal portion and a back surface electrode (first electrode) 51 of the semiconductor chip 50 is electrically connected to the chip mount part 10. A front surface electrode (second electrode) 52 of the semiconductor chip 50 is electrically connected to the electrode connection part 20 being a second metal portion via the metal wire 60. The electrode connection part 20 is separated from the chip mount part 10 and is electrically isolated therefrom by the resin 70 to prevent the back surface electrode 51 and the front surface electrode 52 of the semiconductor chip 50 from short-circuiting with each other.

The metal wire 60 is bonded onto the front surface electrode 52 of the semiconductor chip 50 and the electrode connection part 20 and electrically connects between the front surface electrode 52 and the electrode connection part 20.

The resin 70 is provided to seal around the semiconductor chip 50, the chip mount part 10, and the electrode connection part 20. The resin 70 has a first recess 71 on the second surface F2_10 of the chip mount part 10 and has a second recess 72 on the second surface F2_20 of the electrode connection part 20. The first recess 71 exposes a portion of the chip mount part 10. The second recess 72 exposes a portion of the electrode connection part 20. That is, the resin 70 is not provided in the first and second recesses 71 and 72.

The first terminal part 80 is filled in the first recess 71 and covers the exposed portion of the chip mount part 10. The first terminal part 80 has a third surface F3_80 being in contact with the second surface F2_10 of the chip mount part 10, a fourth surface F4_80 located on the opposite side to the third surface F3_80, and side surfaces F80S located between the third surface F3_80 and the fourth surface F4_80. The first terminal part 80 is electrically connected to the second surface F2_10 of the chip mount part 10 at the third surface F3_80 and is electrically connected to the back surface electrode 51 of the semiconductor chip 50 via the chip mount part 10. This enables a user to supply power to the back surface electrode 51 of the semiconductor chip 50 externally using the first terminal part 80. As shown in FIG. 3D, the first terminal part 80 has the fourth surface F4_80 exposed on the bottom surface of the semiconductor package 100 and is designed to have a size corresponding to a planar size of the second surface F2_10 of the chip mount part 10. A material of the first terminal part 80 is different from those of the chip mount part 10 and the electrode connection part 20 and can be conductive metal such as plating.

The second terminal part 90 is filled in the second recess 72 and covers the exposed portion of the electrode connection part 20. The second terminal part 90 has a third surface F3_90 being in contact with the second surface F2_20 of the electrode connection part 20, a fourth surface F4_90 located on the opposite side to the third surface F3_90, and side surfaces F90S located between the third surface F3_90 and the fourth surface F4_90. The second terminal part 90 is electrically connected to the second surface F2_20 of the electrode connection part 20 at the third surface F3_90 and is electrically connected to the front surface electrode 52 of the semiconductor chip 50 via the electrode connection part 20 and the metal wire 60. This enables a user to supply power to the front surface electrode 52 of the semiconductor chip 50 externally using the second terminal part 90. As shown in FIG. 3D, the second terminal part 90 has the fourth surface F4_90 exposed on the bottom surface of the semiconductor package 100 and is designed to have a size corresponding to a planar size of the second surface F2_20 of the electrode connection part 20. A material of the second terminal part 90 is different from those of the chip mount part 10 and the electrode connection part 20 and can be conductive metal such as plating.

As shown in FIG. 3E, the first terminal part 80 is filled in the first recess 71 and the fourth surface F4_80 of the first terminal part 80 is substantially flush with a front surface F70 of the resin 70. The second terminal part 90 is filled in the second recess 72, and the fourth surface F4_90 of the second terminal part 90 is substantially flush with the front surface F70 of the resin 70. That is, the resin 70 is provided on the second surface F2_10 of the chip mount part 10 and the side surfaces F80S of the first terminal part 80, and is also provided on the second surface F2_20 of the electrode connection part 20 and the side surfaces F90S of the second terminal part 90. Meanwhile, the resin 70 is not provided on the fourth surface F4_80 of the first terminal part 80 and the fourth surface F4_90 of the second terminal part 90. As described above, the semiconductor package 100 according to the present embodiment is an LGA package, for example. To facilitate electrical connection between outside and the terminal parts 80 and 90, the fourth surfaces F4_80 and F4_90 can be formed to somewhat protrude from the front surface F70 of the resin 70. Alternatively, to suppress undesired short-circuiting between outside and the terminal parts 80 and 90, the fourth surfaces F4_80 and F4_90 can be somewhat recessed from the front surface F70 of the resin 70. The semiconductor package 100 is not limited to the LGA package and can be other types of packages.

The chip mount part 10 and the electrode connection part 20 shown in FIGS. 3B and 3C are cut surfaces of the chip mount part 10 and the electrode connection part 20 exposed from the resin 70 when the semiconductor packages 100 are individualized by dicing.

The semiconductor package 100 according to the present embodiment has the lead frame 1 with the first surfaces (F1_10 and F1_20) and the second surfaces (F2_10 and F2_20) both being substantially flat. That is, the lead frame 1 constituting the semiconductor package 100 does not have a half-etched structure and has a flat frame structure. The terminal parts 80 and 90 are formed by filling metal such as plating in the recesses 71 and 72 provided in the resin 70. Therefore, the lead frame 1 of the semiconductor package 100 according to the present embodiment is formed by pressing processing and does not require half-etching processing. Therefore, the manufacturing cost of the lead frame 1 can be reduced.

A manufacturing method of the semiconductor package 100 according to the present embodiment is explained next.

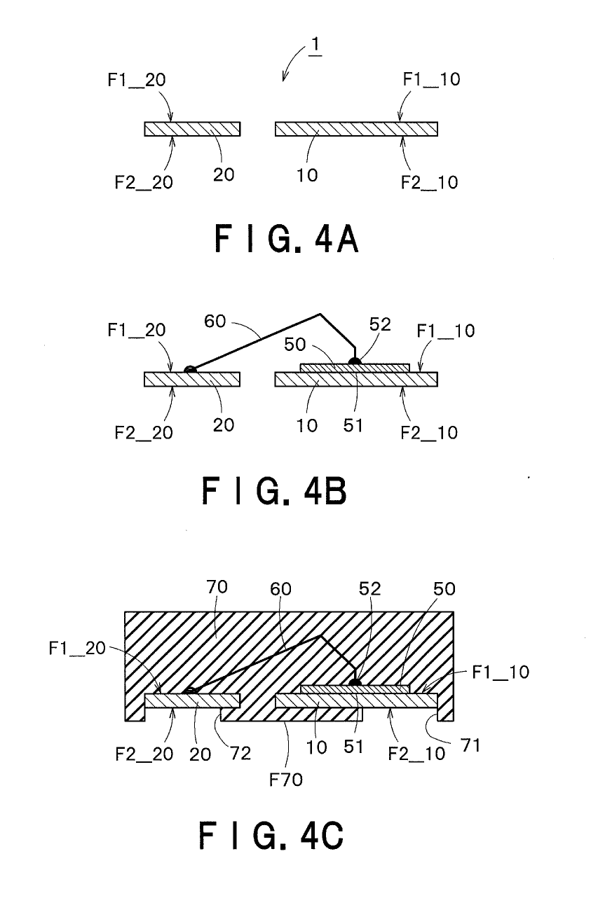

FIGS. 4A to 4C are cross-sectional views showing an example of the manufacturing method of the semiconductor package 100 according to the present embodiment. FIGS. 4A to 4C illustrate cross-sections corresponding to one semiconductor chip 1. Other portions in the lead frame 1 connected by the first suspension leads 30 and the second suspension leads 40 are not shown.

As shown in FIG. 4A, the lead frame 1 having a flat frame structure is first prepared. The chip mount part 10 has the first surface F1_10 and the second surface F2_10 on the opposite side to the first surface F1_10. The electrode connection part 20 has the first surface F1_20 and the second surface F2_20 on the opposite side to the first surface F1_20. The first surfaces F1_10 and F1_20 and the second surfaces F2_10 and F2_20 are all flat.

Next, a solder (not shown) is supplied onto the first surface F1_10 of the chip mount part 10 and the semiconductor chip 50 is mounted on the solder as shown in FIG. 4B. Accordingly, the semiconductor chip 50 is fixed onto the first surface F1_10 of the chip mount part 10. The back surface electrode 51 of the semiconductor chip 50 is electrically connected to the chip mount part 10 of the lead frame 1.

Subsequently, as shown in FIG. 4B, the metal wire 60 is bonded to between the front surface electrode 52 of the semiconductor chip 50 and the first surface F1_20 of the electrode connection part 20. Accordingly, the front surface electrode 52 is electrically connected to the electrode connection part 20.

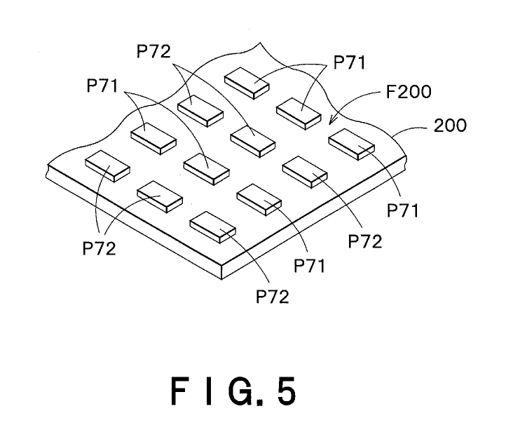

Next, the resin 70 is provided to seal around the semiconductor chip 50, the chip mount part 10, the electrode connection part 20, and the metal wire 60 as shown in FIG. 4C. A mold used in a resin sealing process at that time has protrusions on surfaces facing the second surface F2_10 of the chip mount part 10 and the second surface F2_20 of the electrode connection part 20. FIG. 5 shows a portion of a mold 200.

A surface F200 of the mold 200 in FIG. 5 faces the second surface F2_10 of the chip mount part 10 and the second surface F2_20 of the electrode connection part 20 and has protrusions P71 and P72. The protrusions P71 are provided to correspond to the first recesses 71 for the corresponding semiconductor chips 50, respectively. The protrusions P72 are provided to correspond to the second recesses 72 for the corresponding semiconductor chips 50, respectively.

In the resin sealing process, the protrusions P71 and P72 are in contact with the second surfaces F2_10 of the chip mount parts 10 and the second surfaces F2_20 of the electrode connection parts 20, respectively. Accordingly, the resin 70 does not enter between the protrusion portions P71 and the chip mount parts 10 and between the protrusions P72 and the electrode connection parts 20. Meanwhile, the resin 70 is filled around the protrusions P71 and P72. In this way, the first and second recesses 71 and 72 shown in FIG. 4C are formed on the second surfaces F2_10 of the chip mount parts 10 and the second surfaces F2_20 of the electrode connection parts 20, respectively, and thus regions of the second surfaces F2_10 and F2_20 other than the first and second recesses 71 and 72 are covered with the resin 70. Portions of the second surfaces F2_10 of the chip mount parts 10 and portions of the second surfaces F2_20 of the electrode connection parts 20 are exposed in the first and second recesses 71 and 72, respectively.

Subsequently, plating is formed on the exposed portions of the chip mount parts 10 and the exposed portions of the electrode connection parts 20. Accordingly, the exposed portions of the chip mount parts 10 and the exposed portions of the electrode connection parts 20 are covered with plating and the plating is filled in the first and second recesses 71 and 72. In this way, the first and second terminal parts 80 and 90 are formed in the first and second recesses 71 and 72, respectively. As mentioned above, the first and second terminal parts 80 and 90 can be filled in the first and second recesses 71 and 72 in such a manner that the fourth surfaces F4_80 and F4_90 become substantially flush with the front surface F70 of the resin 70.

Thereafter, in the dicing process, the semiconductor packages 100 are individualized. The semiconductor packages 100 shown in FIGS. 3A to 3E are thereby completed.

According to the present embodiment, the lead frame 1 has a flat frame structure. The terminal parts 80 and 90 are formed by filling metal such as plating in the recesses 71 and 72 formed in the resin 70. Therefore, the lead frame 1 according to the present embodiment does not require the half-etching processing and thus the manufacturing cost thereof can be reduced.

Furthermore, according to the present embodiment, the lead frame 1 is also applicable to other types of semiconductor packages having different shapes or sizes of the terminal parts 80 and 90. In this case, it suffices to change the mold 200 used in the resin sealing process to change the shapes, sizes, or positions of the recesses 71 and 72. Because the terminal parts 80 and 90 are filled in the recesses 71 and 72, the shapes, sizes, and positions of the terminal parts 80 and 90 are determined in a self-aligned manner according to the shapes, sizes, and positions of the recesses 71 and 72, respectively. As described above, the lead frame 1 according to the present embodiment can be also applied in common to other types of semiconductor packages different in the shapes, sizes, and positions of the terminal parts 80 and 90. This enables the lead frame 1 according to the present embodiment to be used in common for a relatively many types of semiconductor packages.

When the lead frame 1 is to be applied to other types of semiconductor packages different in the shapes, sizes, and positions of the terminal parts 80 and 90, the mold 200 needs to be changed. However, the mold 200 is used in common for formation of the same type of semiconductor packages. Therefore, a change of the mold 200 is relatively easier than a change of the lead frame 1 and also the cost is low.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a metal part comprising a first surface and a second surface on an opposite side to the first surface;
a semiconductor chip mounted on the first surface of the metal part and electrically connected to the metal part;
a terminal part comprising a third surface being in contact with the second surface of the metal part, a fourth surface on an opposite side to the third surface, and side surfaces between the third surface and the fourth surface; and
a resin on the second surface of the metal part and the side surfaces of the terminal part.

2. The device of claim 1, wherein
the metal part comprises a first metal portion and a second metal portion, the first metal portion having the semiconductor chip mounted thereon and being electrically connected to a first electrode of the semiconductor chip, the second metal portion being insulated from the first metal portion and being electrically connected to a second electrode of the semiconductor chip,
the terminal part comprises a first terminal part being in contact with a second surface of the first metal portion, and a second terminal part being in contact with a second surface of the second metal portion, and
the resin is located on the second surface of the first metal portion and on side surfaces of the first terminal part and is located on the second surface of the second metal portion and on side surfaces of the second terminal part.

3. The device of claim 1, wherein the fourth surface of the terminal part is substantially flush with a front surface of the resin.

4. The device of claim 2, wherein
a fourth surface of the first terminal part is substantially flush with a front surface of the resin, and
a fourth surface of the second terminal part is substantially flush with the front surface of the resin.

5. The device of claim 1, wherein a material of the terminal part is different from a material of the metal part.

6. The device of claim 2, wherein a material of the terminal part is different from a material of the metal part.

7. The device of claim 1, wherein the resin is not located on the fourth surface of the terminal part.

8. The device of claim 2, wherein the resin is not located on the fourth surface of the terminal part.

9. The device of claim 1, wherein the first surface and the second surface of the metal part are substantially flat.

10. The device of claim 2, wherein the first surface and the second surface of the metal part are substantially flat.

11. A manufacturing method of a semiconductor device, the method comprising:
mounting a semiconductor chip on a first surface of a metal part comprising the first surface and a second surface on an opposite side to the first surface;
forming a resin to form a recess exposing a portion of the metal part on the second surface; and
forming a terminal part electrically connected to the second surface of the metal part in the recess.

12. The method of claim 11, wherein
the metal part comprises a first metal portion and a second metal portion, the first metal portion having the semiconductor chip mounted thereon and being electrically connected to a first electrode of the semiconductor chip, the second metal portion being insulated from the first metal portion and being electrical connected to a second electrode of the semiconductor chip,
formation of the resin comprises forming a first recess exposing a portion of the first metal portion on the second surface of the first metal portion, and forming a second recess exposing a portion of the second metal portion on the second surface of the second metal portion, and
the terminal part comprises a first terminal part and a second terminal part, the first terminal part being formed to be electrically connected to the second surface of the first metal portion in the first recess, the second terminal part being formed to be electrically connected to the second surface of the second metal portion in the second recess.

13. The method of claim 11, wherein the terminal part is formed in the recess in such a manner that a front surface of the terminal part is substantially flush with a front surface of the resin.

14. The method of claim 12, wherein the terminal part is formed in the first and second recesses in such a manner that a front surface of the terminal part is substantially flush with a front surface of the resin.
